(19) United States
(12) Patent Application Publication
(10) Pub. No.: US 2023/0400057 A1
(43) Pub. Date: Dec. 14, 2023

(54) LEVITATING TRANSPORT SYSTEM

(71) Applicant: KABUSHIKI KAISHA YASKAWA DENKI, Kitakyushu-shi (JP)

(72) Inventors: Go YAMAGUCHI, Fukuoka (JP); Yoshiaki KUBOTA, Fukuoka (JP); Yuta HIGASHINAKA, Fukuoka (JP); Mina ORII, Fukuoka (JP); Dai SHIMIZU, Fukuoka (JP)

(21) Appl. No.: 18/331,939

(22) Filed: Jun. 9, 2023

(30) Foreign Application Priority Data
Jun. 13, 2022 (JP) 2022-095205

(51) Int. Cl. F16C 32/04; B25J 19/00; B25J 11/00

(52) U.S. Cl. CPC F16C 32/0451; B25J 19/00; B25J 11/0095; F16C 2326/58

(57) ABSTRACT

A transport system include: a workpiece holder configured to hold a workpiece; a moving body facing the workpiece holder at least in a gravity direction and movable in a movement direction intersecting the gravity direction; a weight reducer configured to apply a static non-contact force to the workpiece holder to reduce a weight of the workpiece holder; a force generator disposed on the moving body to face the workpiece holder in the gravity direction, the force generator configured to apply a controllable non-contact force to the workpiece holder so as to follow a movement of the moving body while levitating the workpiece holder having the reduced weight; and circuitry configured to control the controllable non-contact force generated by the force generator to control a relative position of the workpiece holder with respect to the moving body.

### CROSS-REFERENCE TO RELATED APPLICATIONS

This application is based upon and claims the benefit of priority from Japanese Patent Application No. 2022-095205, filed on Jun. 13, 2022. The entire contents of which are incorporated herein by reference.

### BACKGROUND

### Field

The present disclosure relates to a transport system.

### Description of the Related Art

Japanese Unexamined Patent Publication No. 04-338028 discloses an in-vacuum transporting machine. This transporting machine includes: a partition wall made of a non-magnetic and non-conductive material for partitioning the inside of a vacuum transporting path into an upper vacuum chamber and a lower vacuum chamber; a levitation table made of a conductive material accommodated in the upper vacuum chamber; a bogie accommodated in the lower vacuum chamber and moved by a linear motor; and four levitation coils that magnetically levitate the levitation table by repulsive force due to electromagnetic induction at four corners of the bogie and control the posture and levitation height of the levitation table by independently changing exciting current or exciting frequency.

### SUMMARY

Disclosed herein is a transport system. The transport system may include: a workpiece holder configured to hold a workpiece; a moving body facing the workpiece holder at least in a gravity direction and movable in a movement direction intersecting the gravity direction; a weight reducer configured to apply a static non-contact force to the workpiece holder to reduce a weight of the workpiece holder; a force generator disposed on the moving body to face the workpiece holder in the gravity direction, the force generator configured to apply a controllable non-contact force to the workpiece holder so as to follow a movement of the moving body while levitating the workpiece holder having the reduced weight; and circuitry configured to control the controllable non-contact force generated by the force generator to control a relative position of the workpiece holder with respect to the moving body.

Additionally, another transport system is disclosed herein. The other transport system may include: a workpiece holder configured to hold a workpiece; a moving body disposed above the workpiece holder in a gravity direction and movable in a movement direction intersecting the gravity direction; and a force generator disposed on the moving body to face the workpiece holder in the gravity direction, the force generator configured to apply a controllable non-contact force to the workpiece holder to follow a movement of the moving body while levitating the workpiece holder.

Additionally, another transport system is disclosed herein. The other transport system may include: a workpiece holder configured to hold a workpiece; a moving body facing the workpiece holder at least in a gravity direction and movable in a movement direction intersecting the gravity direction; a force generator disposed on the moving body to face the workpiece holder in the gravity direction, the force generator configured to apply a controllable non-contact force to the workpiece holder to follow a movement of the moving body while levitating the workpiece holder; a first sensor configured to detect a relative position of the workpiece holder with respect to the moving body; a second sensor configured to detect an absolute position of the workpiece holder with respect to a fixed original position; and a circuitry configured to control the controllable non-contact force generated by the force generator to cause the absolute position to follow a target position with respect to the fixed original position by controlling a relative position of the workpiece holder with respect to the moving body based at least in part on the detected relative position and the detected absolute position.

### BRIEF DESCRIPTION OF THE DRAWINGS

FIG. 1 is a schematic view illustrating a transport system.

FIG. 2 is a sectional view taken along line II-II in FIG. 1.

FIG. 3 is a sectional view taken along line III-III in FIG. 2.

FIG. 4 is a sectional view taken along line IV-IV in FIG. 3.

FIG. 5 is an enlarged view of a transport device in FIG. 2.

FIG. 6 is an enlarged view of a workpiece holder in FIG. 5.

FIG. 7 is an enlarged view of a moving body in FIG. 5.

FIG. 8 is a sectional view taken along line VIII-VIII in FIG. 5.

FIG. 9 is a sectional view taken along line IX-IX in FIG. 5.

FIG. 10 is a sectional view taken along line X-X in FIG. 5.

FIG. 11 is a block diagram illustrating a hardware configuration of a control unit;

FIG. 12 is a drawing illustrating a cooling system in FIG. 5.

FIG. 13 is a sectional view taken along line XIII-XIII in FIG. 12.

FIG. 14 is a schematic view illustrating a state in which a side unit is removed from the transport device.

FIG. 15 is a schematic view illustrating a state in which a side unit is removed from the transport device.

### DETAILED DESCRIPTION

In the following description, with reference to the drawings, the same reference numbers are assigned to the same components or to similar components having the same function, and overlapping description is omitted.

Transport System

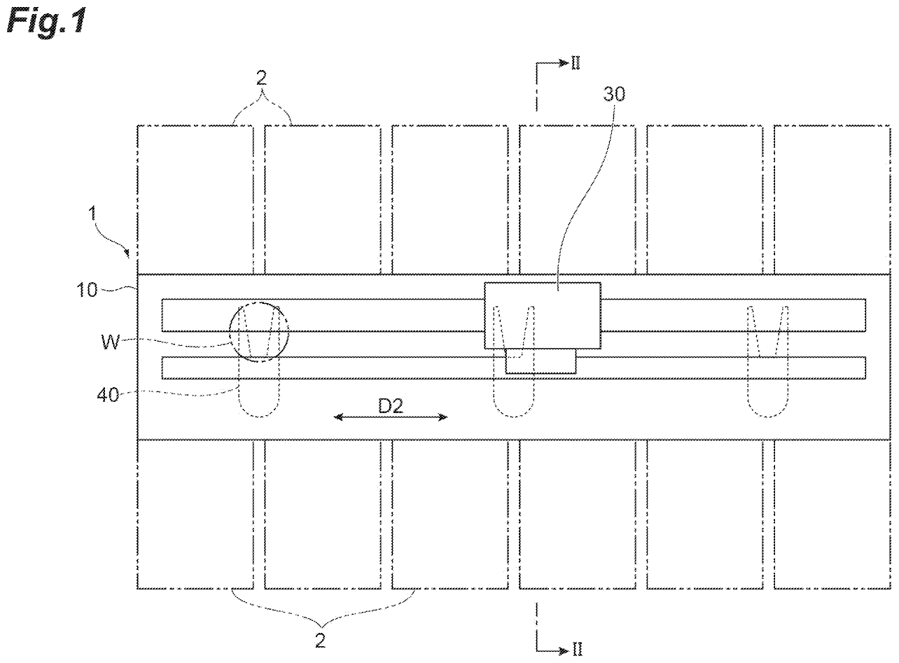

A transport system 1 illustrated in FIG. 1 is a system for transporting a workpiece W. Examples of the workpiece W include a substrate. Examples of the substrate that can be the workpiece W include a semiconductor substrate, a glass substrate, a mask substrate, and a flat panel display (FPD) substrate. For example, the transport system 1, in a substrate processing system, transports the workpiece W between a plurality of processing units that perform processing on the workpiece W. The processing includes various types of processing (film formation, etching, and the like) on the workpiece W, and temporarily storing the workpiece W in a predetermined environment.

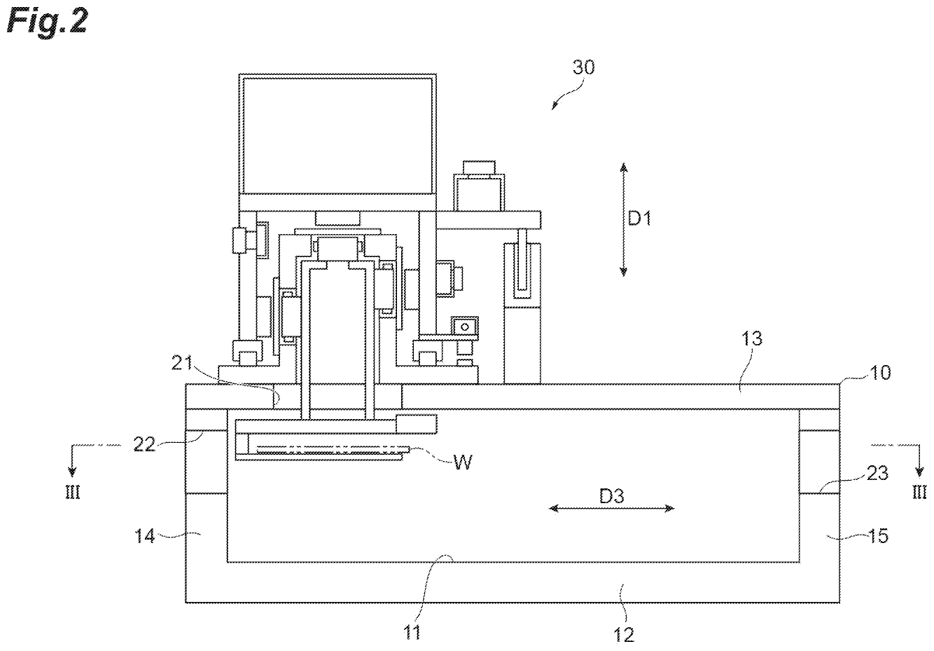

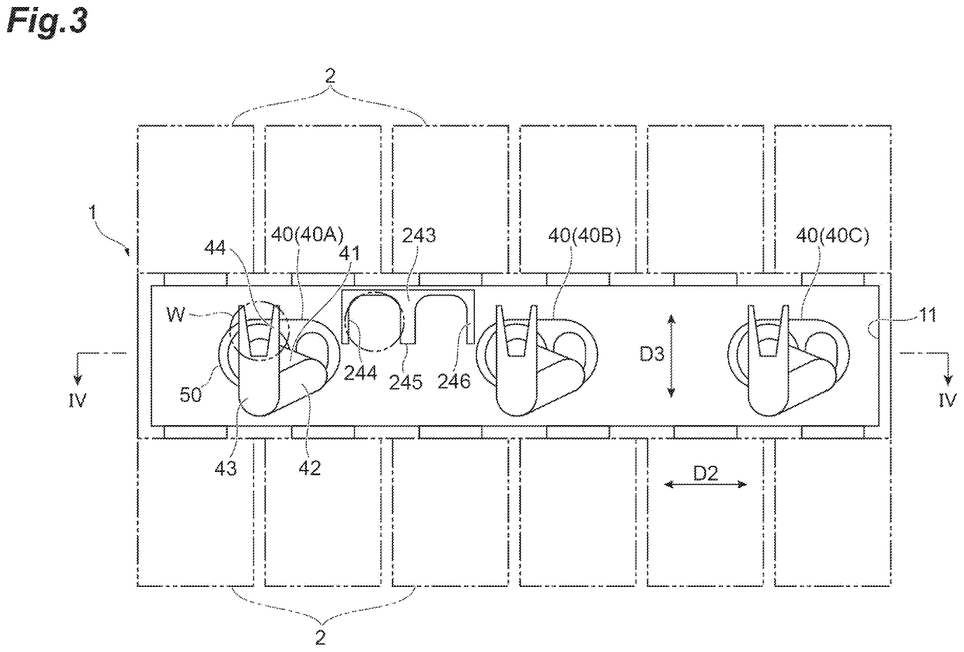

As illustrated in FIG. 1, the transport system 1 includes a transport housing 10, a transport device 30, and at least one robot 40. The transport housing 10 contains the workpiece W that is transported between a plurality of processing units 2. For example, the transport housing 10 extends along a movement direction D2 that intersects (for example, is orthogonal to) a gravity direction D1 (vertical direction). As illustrated in FIG. 2, the transport housing 10 includes a transport chamber 11, a base plate 12, a top plate 13, and side walls 14, 15. The transport chamber 11 accommodates the workpiece W. The base plate 12 partitions a space below the transport chamber 11 and the transport chamber 11. The top plate 13 partitions a space above the transport chamber 11 and the transport chamber 11. The side plates 14, 15 partition spaces adjacent to both sides of the transport chamber and the transport chamber 11 in a width direction D3 that intersects (for example, is orthogonal to) the gravity direction D1 and the movement direction D2. The processing units 2 arranged along the movement direction D2 are adjacent to the side wall 14. A plurality of loading/unloading ports 22 respectively corresponding to the processing units 2 are formed in the side wall 14. Processing units 2 other than the processing units 2 adjacent to the side wall 14 may be arranged along the movement direction D2 and be adjacent to the side wall 15 (see FIG. 3). A plurality of loading/unloading ports 23 respectively corresponding to the processing units 2 are formed in the side wall 15.

The transport device 30 transports the workpiece W along the movement direction D2 in the transport chamber 11. For example, the transport device 30 is mounted on the top plate 13 of the transport housing 10. In the top plate 13 of the transport housing 10, a communication port 21 extending along the movement direction D2 is formed. The transport device 30 is mounted on the top plate 13 and holds the workpiece W in the transport chamber 11 via the communication port 21 and transports it along the movement direction D2. In the width direction D3, the communication port 21 and the transport device 30 may be located closer to the side wall 14 or closer to the side wall 15. As an example, the illustrated the communication port 21 and the transport device 30 are located closer to the side wall 14.

The transport device 30 cooperates with the robot 40 to transport the workpiece W between the processing units 2. In cooperation with the transport device 30, the robot 40 receives the workpiece W from the transport device 30, loads it into any of the processing units 2, unloads the workpiece W from any of the processing units 2, and delivers it to the transport device 30. For example, the robot 40 is mounted on the base plate 12 and transports the workpiece W above the base plate 12.

As illustrated in FIG. 3, the transport system 1 may include two or more robots 40 positioned at different locations in the movement direction D2. In one example illustrated in FIG. 3, the transport system 1 includes a robot 40A, a robot 40B, and a robot 40C arranged in order along the movement direction D2. The transport device 30 may transport the workpiece W between the robot 40A and the robot 40B, may transport the workpiece W between the robot 40B and the robot 40C, and may transport the workpiece W between the robot 40A and the robot 40C.

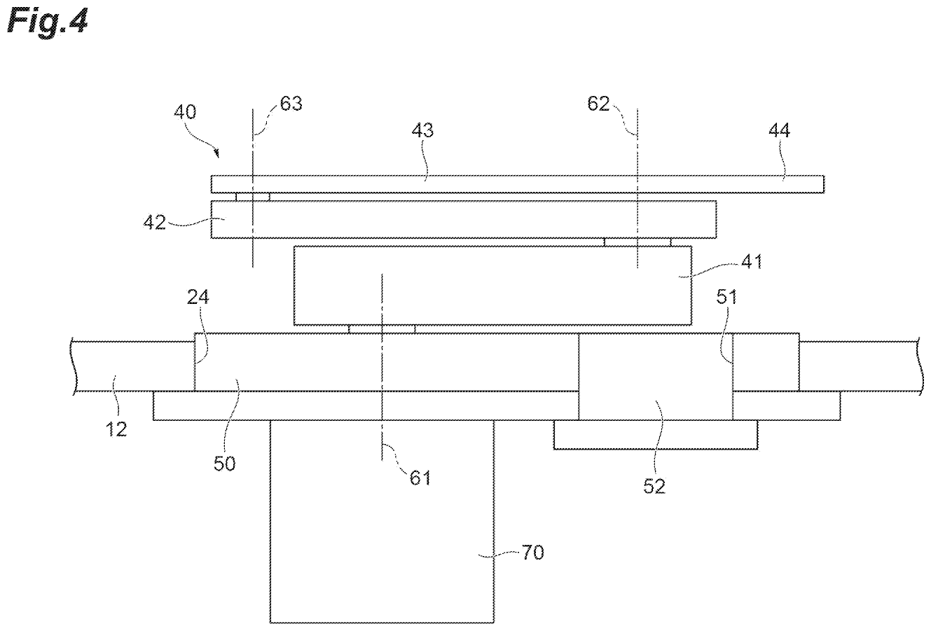

As illustrated in FIG. 4, the robot 40 includes a flange 50, an arm 41, an arm 42, an arm 43, and a substrate support 44. The flange 50 is attached to the base plate 12. For example, the base plate 12 is formed with a robot mounting port 24 for mounting the robot 40, and the flange is attached to the base plate 12 to occlude the robot mounting port 24.

The arm 41 is mounted on the flange 50 to pivot about a first axis 61 along the gravity direction D1 and extends away from the first axis 61. The arm 42 is mounted on the end of the arm 41 to pivot about a second axis 62 along the gravity direction D1 and extend away from the second axis 62. The arm 43 is mounted on the end of the arm 42 to pivot about a third axis 63 along the gravity direction D1 and extend away from the second axis 62. The substrate support 44 is formed at the end of the arm 43 to hold the workpiece W. “Holding” also includes simply supporting from below. The same applies to the following description.

An actuator unit 70 rotates the arm 41 about the first axis 61, rotates the arm 42 about the second axis 62, and rotates the arm 43 about the third axis 63 by one or more electric motors. Thus, the position and posture of the substrate support 44 in the horizontal plane are freely changed within the movable range of the robot 40. For example, the actuator unit 70 is mounted under the flange 50. With the flange 50 attached to the base plate 12, the actuator unit 70 is placed outside of the transport chamber 11 (for example, under the base plate 12).

The robot 40 may further include a maintenance opening 51 and a blocking member 52. The maintenance opening 51 passes through the flange 50 along the gravity direction D1. The blocking member 52 occludes the maintenance opening 51. By removing the blocking member 52, inspection and repair of the arm 41, the arm 42, the arm 43, the substrate support 44 and the like can readily be performed through the maintenance opening 51.

If the transport device 30 is placed on the transport housing 10 as in this example, the transport device 30 may interfere and make it difficult to inspect and repair the arm 41, the arm 42, the arm 43, and the substrate support 44 from above. In such a case, a configuration that allows performing inspection and repair of the arm 41, the arm 42, the arm 43, the substrate support 44, and the like via the maintenance opening 51 is more beneficial.

The configuration of the transport system 1 illustrated above is merely an example, and can be modified. For example, the transport device 30 may be mounted on the base plate 12 and the robot 40 may be mounted on the top plate 13. Both the transport device 30 and the robot may be mounted on the base plate 12 and both the transport device 30 and the robot 40 may be mounted on the top plate 13.

Transport Device

Hereinafter, the configuration of the transport device will be described in more detail. The transport system 1 is configured to prevent generation of particles in the transport chamber 11. For example, the transport device includes a workpiece holder 200, a moving body 300, a force generator 510, and a control unit 900. The workpiece holder 200 can hold the workpiece W in the transport chamber 11. The moving body 300 is located outside the transport chamber 11, faces the workpiece holder 200 in at least the gravity direction D1, and is movable in the movement direction D2. The force generator 510 is configured to apply a non-contact force (a controllable non-contact force F02) to the workpiece holder 200 so as to follow the movement of the moving body 300 while levitating the workpiece holder 200. The control unit 900 controls the non-contact force of the force generator 510 to control a relative position at least one of the position and posture of the workpiece holder 200 of the workpiece holder 200 with respect to the moving body 300 (at least one of the position and posture of the workpiece holder 200 with respect to the moving body 300).

Levitating means a state of being kept so as not to come into contact with an object below against gravity. Following the movement of the moving body 300 means moving together with the moving body 300 so as to maintain the relative position with respect to the moving body 300 within a predetermined range.

With the above-described configuration, the workpiece holder 200 may be placed in the transport chamber 11 while placing the moving body 300 outside the transport chamber 11, and to move the workpiece holder 200 in the transport chamber 11 without placing the drive source that causes generation of particles in the transport chamber 11. In addition, since the workpiece holder 200 is levitated, generation of particles due to contact between an object below (for example, the base plate 12) and the workpiece holder 200 is also prevented.

When all of the non-contact force that causes the workpiece holder 200 to levitate is generated by the force generator 510, the energy consumed by the force generator 510 increases. Thus, the transport system 1 further includes a weight reducer 400. The weight reducer 400 is configured to generate a static non-contact force. The static non-contact force is a non-contact force generated by a static energy field. The static energy field is an energy field that cannot be changed by providing an electric power. The static energy field may be a magnetic field generated by a permanent magnet. The weight reducer 400 generates an attractive force F01 or repulsive force with the workpiece holder 200 to reduce the weight of the workpiece holder 200.

Thus, the non-contact force generated for levitating the workpiece holder 200 can be reduced. Therefore, the energy consumption for generating the non-contact force can be reduced. Accordingly, power consumption may be reduced.

The non-contact force generated by the force generator 510 is an active (controllable) non-contact force that can be changed by supplying energy, such as electric power. The attractive force or repulsive force generated by the weight reducer 400 is, for example, a passive (static) non-contact force that is not changed by the supply of energy such as electric power and is determined in accordance with the arrangement relationship between the workpiece holder 200 and the moving body 300. It should be noted that a minute change in the magnetic force of the permanent magnet due to heat generation accompanying the supply of energy is not included in the active change in force.

Examples of the attractive force generated by the weight reducer 400 include an attractive force generated between permanent magnets and an attractive force generated between a permanent magnet and a soft magnetic member (for example, steel). An example of the repulsive force generated by the weight reducer 400 is a repulsive force generated between permanent magnets.

When applying a passive attractive force to the workpiece holder 200, the weight reducer 400 is configured to generate an attractive force on the workpiece holder 200 from above. When applying a passive repulsive force to the workpiece holder 200, the weight reducer 400 is configured to generate a repulsive force on the workpiece holder 200 from below.

The weight reducer 400 generates an attractive force or a repulsive force between the magnetic material disposed in the workpiece holder 200. The magnetic member disposed in the workpiece holder 200 may be a permanent magnet or a soft magnetic member. If the permanent magnet is disposed in the workpiece holder 200, the weight reducer 400 includes a permanent magnet or a soft magnetic member that generates an attractive force with the permanent magnet disposed in the workpiece holder 200. If a soft magnetic member is disposed in the workpiece holder 200, the weight reducer 400 includes a permanent magnet that generates an attractive force with the soft magnetic member disposed in the workpiece holder 200. At least one of the workpiece holder 200 and the weight reducer 400 may include both the permanent magnet and the soft magnetic member.

As described above, with the configuration in which an attractive force or a repulsive force is generated between the permanent magnets or between the permanent magnet and the soft magnetic member, gravity may be reduced without consuming electric power. In addition, even in maintenance work performed without supplying electric power, the position of the workpiece holder 200 may be kept near the moving body 300 by making the workpiece holder 200 follow the movement of the moving body 300. Thus, recovery work after maintenance is facilitated.

The weight reducer 400 may be placed in the moving body 300 and configured to generate an attractive or repulsive force with the workpiece holder 200. By providing the weight reducer 400 on the moving body 300 which is less displaced relative to the workpiece holder 200, the weight reducer 400 can be made compact. The weight reducer 400 may not be placed in the moving body 300 and may apply an attractive or repulsive force to the workpiece holder 200 from a different location than the location of the moving body 300. For example, the weight reducer 400 may extend throughout the range of motion of the workpiece holder 200 along the movement direction D2, such that an attractive or repulsive force can be applied to the workpiece holder 200 without moving with the moving body 300.

The moving body 300 may be arranged to face the workpiece holder 200 from above, and may be arranged to face the workpiece holder 200 from below. For example, as described above, in a configuration where the transport device 30 is mounted on the top plate 13 of the transport housing 10, the moving body 300 is positioned to face the workpiece holder 200 from above. In the configuration where the transport device 30 is mounted on the base plate 12 of the transport housing 10, the moving body 300 is positioned to face the workpiece holder 200 from below.

When the moving body 300 is placed on the workpiece holder 200, the weight reducer 400 placed in the moving body 300 generates an attractive force with the workpiece holder 200. With the configuration in which the weight reducer 400 generates an attractive force with the workpiece holder 200, for example, an object to which the attractive force generated by the permanent magnets is applied can be made of soft magnetic materials, and the use of the magnets can be reduced. When the moving body 300 is placed under the workpiece holder 200, the weight reducer 400 placed in the moving body 300 generates a repulsive force with the workpiece holder 200.

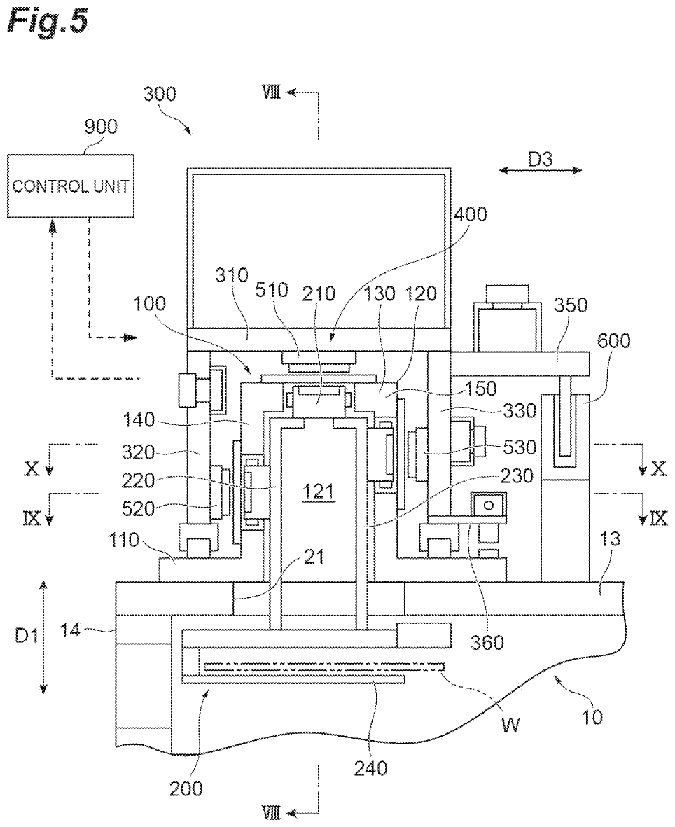

Hereinafter, an example configuration of the transport device 30 will be described in the case where the transport device 30 is mounted on the top plate 13 of the transport housing 10 as described above. As illustrated in FIG. 5, the transport system 1 includes a sub-housing 100, the workpiece holder 200, the moving body 300, the force generator 510, the weight reducer 400, side force generators 520, 530, a driver 600, a sensor 700, a relative sensor 800, and the control unit 900. Each of example configurations will be described below.

Sub Housing

The sub-housing 100 occludes the communication port 21 of the top plate 13 and partitions the inside of the transport chamber 11 from the outside of the transport chamber 11 while housing at least a part of the workpiece holder 200. The sub-housing 100 is made of a substantially non-magnetic material such as an aluminum-based metallic material, and includes a base plate 110, a protruding portion 120, an upper partition wall 130, and side partition walls 140, 150. The base plate 110 is attached to the top surface of the top plate 13 to occlude the communication port 21. The protruding portion 120 projects upwardly from the top plate 13 and extends along the movement direction D2.

The protruding portion 120 includes an accommodation chamber 121, the upper partition wall 130, the side partition wall 140, and the side partition wall 150. The accommodation chamber 121 opens toward the transport chamber 11 and houses the top of the workpiece holder 200. Hereinafter, it is assumed that the accommodation chamber 121 is also included in the transport chamber 11.

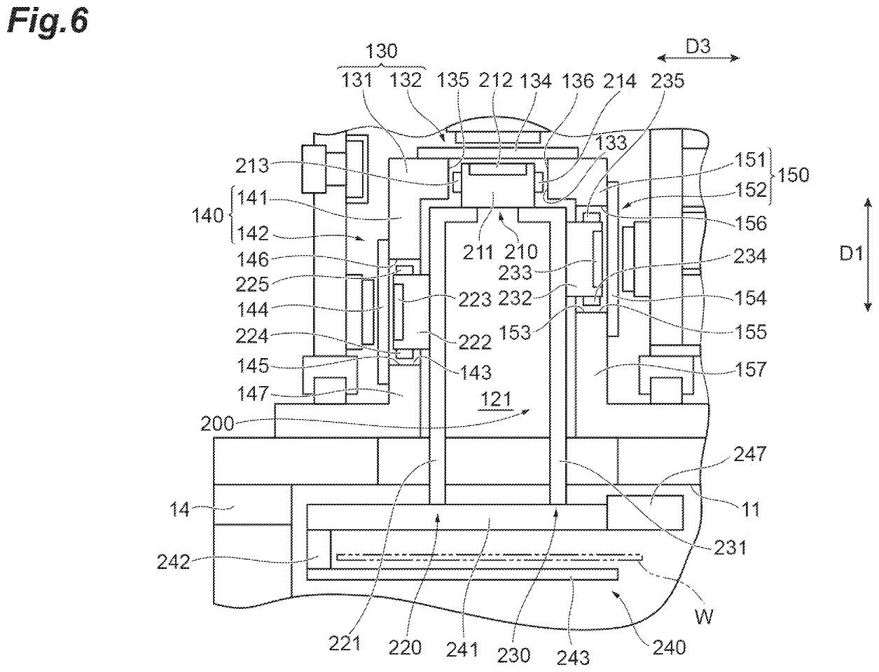

As illustrated in FIG. 6, the upper partition wall 130 partitions the space above the accommodation chamber 121 and the accommodation chamber 121. The upper partition wall 130 includes a wall body 131 and a window 132. The wall body 131 extends along a plane that intersects (for example, is orthogonal to) the gravity direction D1. The window 132 is a thin-walled portion formed in the wall body 131 to improve the transmissibility of the non-contact force. The window 132 includes a window opening 133 and a cover 134. The window opening 133 extends along the movement direction D2 and penetrates up and down through the wall body 131. The cover 134 is made of a plate material such as a resin material, and is fixed to an outer surface of the wall body 131 so as to occlude the window opening 133. The thickness of the cover 134 is less than the thickness of the wall body 131.

The side partition walls 140, 150 partition the space adjacent to both sides of the accommodation chamber 121 in the width direction D3, and the accommodation chamber 121, respectively. The side partition wall 140 is located between a lateral facing portion 320 described below and the workpiece holder 200. The side partition wall 140 includes a wall body 141 and a window 142. The wall body 141 extends along a plane that intersects (for example, is orthogonal to) the width direction D3. The window 142 is a thin-walled portion formed in the wall body 141 to improve the transmissibility of a side non-contact force (described below). The window 142 includes a window opening 143 and a cover 144. The window opening 143 extends along the movement direction D2 and penetrates through the wall body 141 in a direction along the width direction D3. The cover 144 is made of a plate material such as a plastic material, and is fixed to an outer surface of the wall body 141 so as to occlude the window opening 143. The thickness of the cover 144 is less than the thickness of the wall body 141. The portion of the wall body 141 below the window opening 143 (a support wall 147) supports the window 142 and is located below a side magnet array 223 described below.

The side partition wall 150 includes a wall body 151 and a window 152. The wall body 151 extends along a plane that intersects (for example, is orthogonal to) the width direction D3. The window 152 is a thin-walled portion formed in the wall body 151 to improve the transmissibility of a side non-contact force (described below). The window 152 includes a window opening 153 and a cover 154. The window opening 153 extends along the movement direction D2 and penetrates through the wall body 151 in a direction along the width direction D3. The cover 154 is made of a plate material such as a plastic material, and is fixed to an outer surface of the wall body 151 so as to occlude the window opening 153. The thickness of the cover 154 is less than the thickness of the wall body 151. The portion of the wall body 151 below the window opening 153 (a support wall 157) supports the window 152 and is located below a side magnet array 233 described below. The side partition wall 150 is located between a lateral facing portion 330 described below and the workpiece holder 200.

Workpiece Holder

The workpiece holder 200 is be placed in the transport chamber 11 and capable of holding the workpiece W. The workpiece holder 200 is made of a substantially non-magnetic material such as an aluminum-based metallic material, and includes an upper unit 210, side units 220, 230, and a holding unit 240. The upper unit 210 faces the moving body 300 in the gravity direction D1. The upper unit 210 includes an upper magnet base 211. The upper magnet base 211 extends along the movement direction D2 in the upper portion of the accommodation chamber 121 and faces the upper partition wall 130. A magnet array 212 to be described later is placed on the upper magnet base 211. The magnet array 212 is provided on the upper magnet base 211 and faces the window 132. For example, at least a portion of the upper unit 210 are tucked into the window opening 133 of the window 132, and the magnet array 212 faces the cover 134 in the window opening 133.

The window opening 133 includes lateral inner surfaces 135, 136 that face each other in the width direction D3. In the width direction D3, the width of the upper unit 210 is smaller than the opening width of the window opening 133 (the interval between the lateral inner surface 135 and the lateral inner surface 136). Thus, when the upper unit 210 is placed in the center of the window opening 133 in the width direction D3, the upper unit 210 does not touch any of the lateral inner surfaces 135, 136.

Rollers 213, 214 are provided on each side of the upper magnet base 211 in the width direction D3 respectively. The roller 213 is located between the lateral inner surface 135 and the upper magnet base 211. The roller 214 is located between the lateral inner surface 136 and the upper magnet base 211. Each of the rollers 213, 214 is mounted on the upper magnet base 211 so as to rotate about an axis parallel to the gravity direction D1. As the upper unit 210 approaches the lateral inner surface 135 in the window opening 133, the roller 213 contacts the lateral inner surface 135 and rolls in response to movement of the upper unit 210 along the movement direction D2. As the upper unit 210 approaches the lateral inner surface 136 in the window opening 133, the roller 214 contacts the lateral inner surface 136 and rolls in response to movement of the upper unit 210 along the movement direction D2. The upper unit 210 may include a plurality of rollers 213 aligned with the movement direction D2 between the lateral inner surface 135 and the upper unit 210 and a plurality of rollers 214 aligned with the movement direction D2 between the lateral inner surface 136 and the upper unit 210.

In the workpiece holder 200, the side units 220, 230 are placed on each side of the width direction D3 respectively and attached to the upper unit 210. A side unit 220 includes a side frame 221, a side magnet base 222, a roller 224, and a roller 225. The side frame 221 extends downwardly from the upper unit 210 and faces the side partition wall 140. The side magnet base 222 protrudes from the side frame 221 toward the side partition wall 140 and extends along the movement direction D2. The side magnet base 222 supports the side magnet array 223 described below.

The side magnet array 223 is placed on the side of the side magnet base 222 (the side facing the side partition wall 140) and faces the window 142. For example, at least a portion of the side magnet base 222 is tucked into the window opening 143 of the window 142, and the side magnet array 223 faces the cover 144 in the window opening 143.

The window opening 143 includes a lower inner surface 145 and an upper inner surface 146 that face each other in the gravity direction D1. In the gravity direction D1, the height of the side unit 220 is smaller than the opening height of the window opening 143 (the interval between the lower inner surface 145 and the upper inner surface 146). Thus, when the side unit 220 is placed in the center of the window opening 143 in the gravity direction D1, the side unit 220 does not contact either the lower inner surface 145 or the upper inner surface 146.

The roller 224 is placed under the side magnet base 222 (under the side magnet array 223) and is located between the lower inner surface 145 and the side magnet base 222. The roller 225 is placed on the side magnet base 222 (on the side magnet array 223) and is located between the upper inner surface 146 and the side magnet base 222. Each of the rollers 224, 225 is provided on the side magnet base 222 so as to rotate about an axis parallel to the width direction D3. When the side unit 220 is supported on the support wall 147, the roller 224 contacts the support wall 147 and rolls in response to the movement of the side unit 220. For example, in the window opening 143, when the side unit 220 approaches (lowers) the lower inner surface 145, the roller 224 contacts the lower inner surface 145 and rolls in response to movement of the side unit 220 along the movement direction D2. In the window opening 143, when the side unit 220 approaches (rises) the upper inner surface 146, the roller 225 contacts the upper inner surface 146 and rolls in response to movement of the side magnet base 222 along the movement direction D2. The side unit 220 may include a plurality of rollers 224 aligned with the movement direction D2 with the lower inner surface 145 and a plurality of rollers 225 aligned with the movement direction D2 with the upper inner surface 146.

A side unit 230 has a side frame 231, a side magnet base 232, and rollers 234, 235. The side frame 231 extends downwardly from the upper unit 210 and faces the side partition wall 150. The side magnet base 232 protrudes from the side frame 231 toward the side partition wall 150 and extends along the movement direction D2. The side magnet base 232 supports the side magnet array 233 described below.

The side magnet array 233 is placed on the side of the side magnet base 232 (the side facing the side partition wall 150) and faces the window 152. For example, at least a portion of the side magnet base 232 is tucked into the window opening 153 of the window 152, and the side magnet array 233 faces the cover 154 in the window opening 153.

The window opening 153 includes a lower inner surface 155 and an upper inner surface 156 that face each other in the gravity direction D1. In the gravity direction D1, the height of the side unit 230 is smaller than the opening height of the window opening 153 (the interval between the lower inner surface 155 and the upper inner surface 156). Thus, when the side unit 230 is placed in the center of the window opening 153 in the gravity direction D1, the side unit 230 does not contact either the lower inner surface 155 or the upper inner surface 156.

A roller 234 is placed under the side magnet base 232 (under the side magnet array 233) and is located between the lower inner surface 155 and the side magnet base 232. A roller 235 is placed on the side magnet base 232 (on the side magnet array 233) and is located between the upper inner surface 156 and the side magnet base 232. Each of the rollers 234, 235 is mounted on the side magnet base 232 so as to rotate about an axis parallel to the width direction D3. When the side unit 230 is supported on the support wall 157, the roller 234 contacts the support wall 157 and rolls in response to the movement of the side unit 230. For example, in the window opening 153, when the side unit 230 approaches (lowers) the lower inner surface 155, the roller 234 contacts the lower inner surface 155 and rolls in response to movement of the side unit 230 along the movement direction D2. In the window opening 153, when the side unit 230 approaches (rises) the upper inner surface 156, the roller 235 contacts the upper inner surface 156 and rolls in response to movement of the side magnet base 232 along the movement direction D2. The side unit 230 may include a plurality of rollers 234 aligned with the movement direction D2 between the lower inner surface 155 and the side unit 230 and a plurality of rollers 235 aligned with the movement direction D2 between the upper inner surface 156 and the side unit 230.

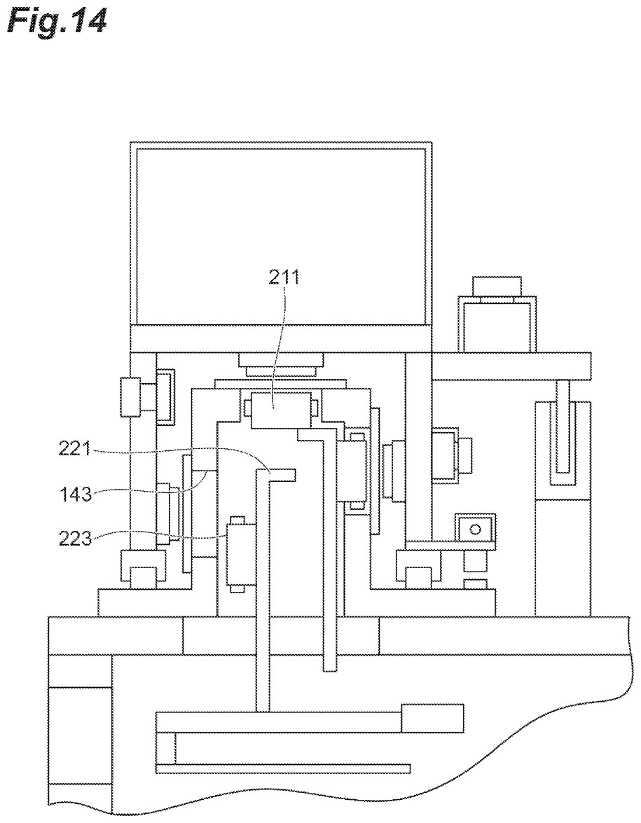

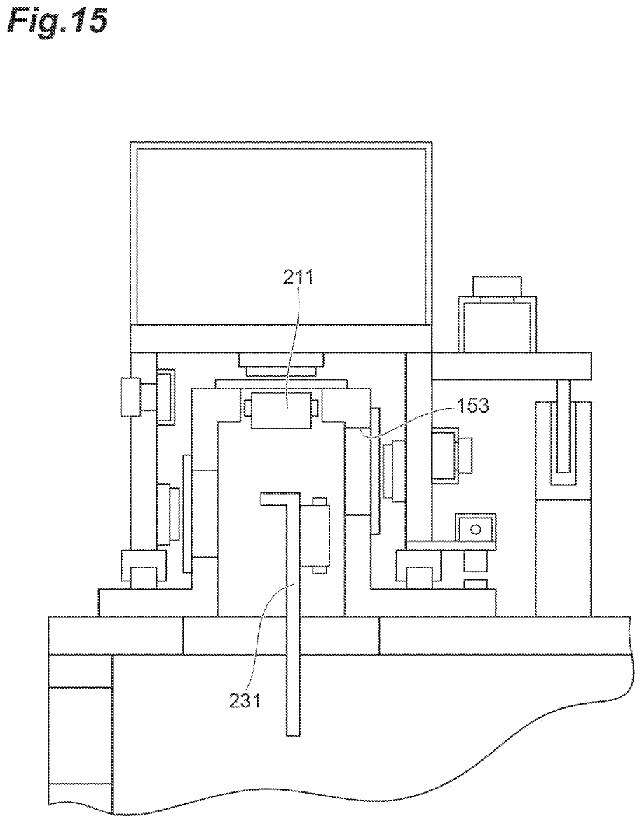

The upper magnet base 211, the side frame 221 and the side frame 231 may be separable from one another. For example, each of the side frames 221, 231 may be attached to the upper magnet base 211 by a detachable method such as bolt fastening. The workpiece holder 200 can readily be taken out from the accommodation chamber 121 for maintenance. For example, the side frame 221 can be removed from the upper magnet base 211 and moved away from the wall body 141 to bring the side magnet array 223 out of the window opening 143 and allow the side frame 221 to be removed downward (see FIG. 14). Similarly, the side frame 231 can be removed from the upper magnet base 211 and moved away from the wall body 151 to bring the side magnet array 233 out of the window opening 153 and allow the side frame 231 to be removed downward (see FIG. 15).

Returning to FIG. 6, the holding unit 240 supports the workpiece W in the transport chamber 11. For example, the holding unit 240 includes an upper frame 241, a post 242, and a substrate support 243. The upper frame 241 is fixed to the lower end of at least one of the side frame 221 and the side frame 231 and is located in the upper part of the transport chamber 11. The upper frame 241 extends from the lower end of the side frame 221 toward the side wall 14. The post 242 extends downward from a portion of the upper frame 241 proximate the side wall 14. The substrate support 243 extends from the lower end of the post 242 in a direction away from the side wall 14 and supports the workpiece W from below.

By way of example, the substrate support 243 is configured to support a plurality of workpiece W arranged along the movement direction D2. For example, as illustrated in FIG. 3, the substrate support 243 includes supports 244, 245 246 arranged in the movement direction D2, and support one the workpiece W with the supports 244, 245 and support one the workpiece W with the supports 245, 246.

The substrate support 243 may be configured to support a plurality of workpieces W in multiple tiers on the gravity direction D1. The substrate support 243 may not be configured to support more than one workpieces W, and may be configured to support one workpiece W alone.

The configuration of the workpiece holder 200 can be modified in any way as long as it can support the workpiece W in the transport chamber 11. For example, the workpiece holder 200 itself may include the arm 41, the arm 42, the arm 43, and the substrate support 44 similar to those of the robot 40. Since the workpiece holder 200 can carry the workpiece W into and out of the processing unit 2 by itself, the robot 40 may not be provided separately from the transport device 30.

Moving Body

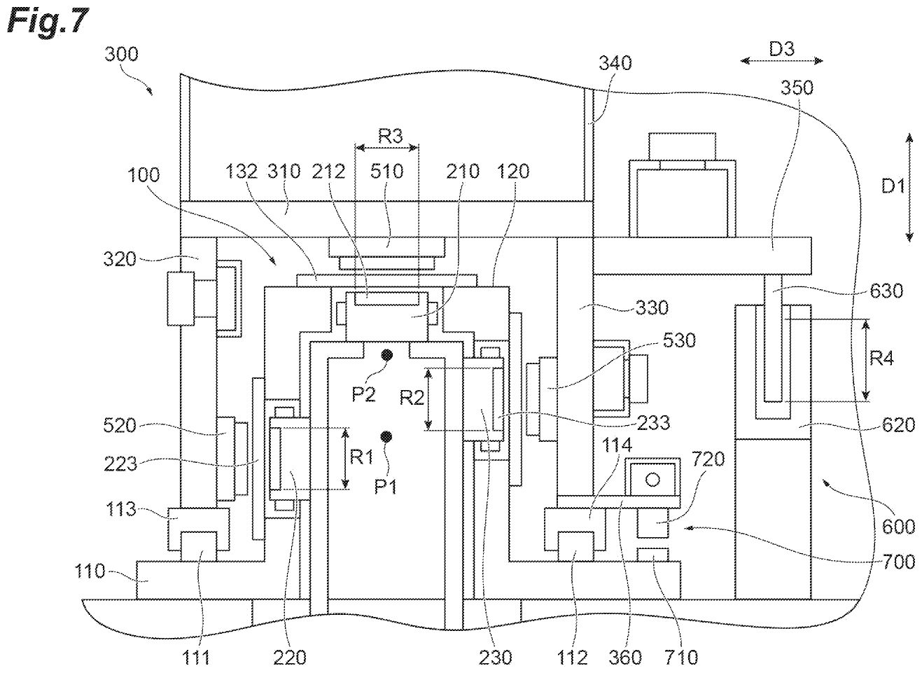

As illustrated in FIG. 7, the moving body 300 is placed outside the transport chamber 11, facing the workpiece holder 200 in at least the gravity direction D1, and able to move in the movement direction D2. For example, the moving body 300 is supported by the base plate 110 of the sub-housing 100 so as to be movable along the movement direction D2, and faces the workpiece holder 200 across the protruding portion 120. As an example, on the base plate 110, linear guides 111, 112 are provided on each side of the protruding portion 120 in the width direction D3, respectively. The linear guides 111, 112 each have movable portions 113, 114 movable along the movement direction D2. The moving body 300 is fixed to the movable portions 113, 114.

The moving body 300 moves between a position that allows delivery of the workpiece W between the robot 40A and the workpiece holder 200 (first position) and a position that allows delivery of the workpiece W between the robot 40B and the workpiece holder 200 (second position). The moving body 300 also moves between a position that allows delivery of the workpiece W between the robot 40B and the workpiece holder 200 (first position) and a position that allows delivery of the workpiece W between the robot 40C and the workpiece holder 200 (second position). Further, the moving body 300 moves between a position that allows delivery of the workpiece W between the robot 40A and the workpiece holder 200 (first position) and a position that allows delivery of the workpiece W between the robot 40C and the workpiece holder 200 (second position).

The moving body 300 is made of a substantially non-magnetic material such as an aluminum-based metallic material, and includes an upper facing portion 310, the lateral facing portion 320, the lateral facing portion 330, a case 340, a driven arm 350, and a sensor holder 360. As illustrated in FIG. 7, the upper facing portion 310 faces the upper partition wall 130 from above and faces the upper unit 210 in the protruding portion 120 across the upper partition wall 130. The lateral facing portion 320 and the lateral facing portion 330 face the workpiece holder 200 on each side of the width direction D3, respectively.

The lateral facing portion 320 extends downward from the upper facing portion 310, faces the side partition wall 140 in the width direction D3, and faces the side unit 220 in the protruding portion 120 across the side partition wall 140. The lateral facing portion 330 extends downward from the upper facing portion 310, faces the side partition wall 150 in the width direction D3, and faces the side unit 230 in the protruding portion 120 across the side partition wall 150. The lower end of the lateral facing portion 320 is fixed on a movable portion 113 of a linear guide 111 and the lower end of the lateral facing portion 330 is fixed on a movable portion 114 of a linear guide 112. This allows the moving body 300 to move along the movement direction D2.

The case 340 is provided on the upper facing portion 310 and houses circuitry and the like constituting at least a part of the control unit 900. The driven arm 350 protrudes from the lateral facing portion 330 along the width direction D3 and is connected to the driver 600 as described below. The driven arm 350 transmits a driving force from the driver 600 to the lateral facing portion 330 to move the moving body 300 along the movement direction D2. Below the driven arm 350, the sensor holder 360 protrudes from the lateral facing portion 330 along the width direction D3 and supports a reader 720 of the sensor 700 described below.

Force Generator

The force generator 510 is placed in the moving body 300 to face the workpiece holder 200 in the gravity direction D1 and applies a non-contact force to the workpiece holder 200 to follow the movement of the moving body 300 while levitating the workpiece holder 200. For example, the force generator 510 is placed under the upper facing portion 310. The force generator 510 faces the window 132 from above and faces the magnet array 212 in the protruding portion 120 across the window 132.

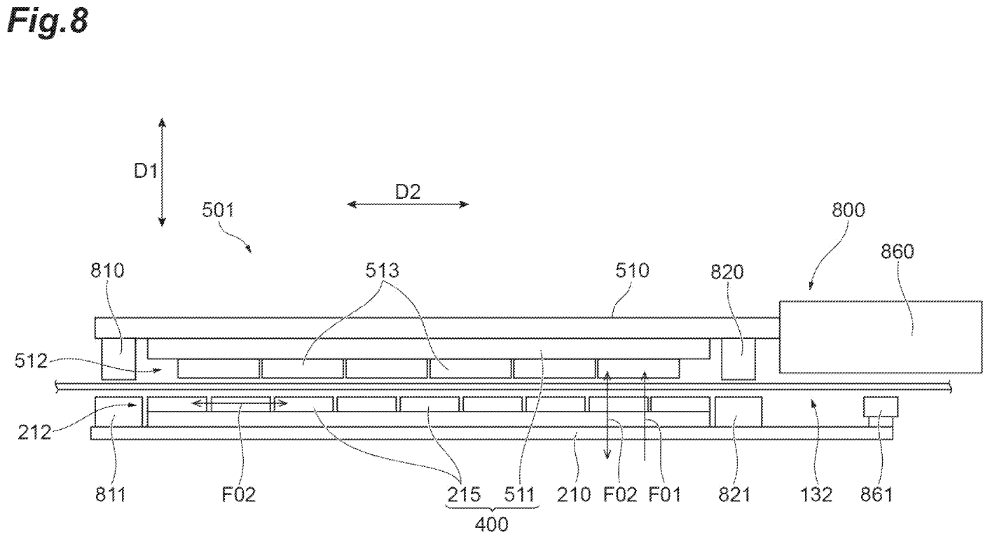

As illustrated in FIG. 8, the force generator 510 includes a back yoke 511 and a coil array 512. The coil array 512 constitutes a linear actuator 501 with the magnet array 212 placed in the workpiece holder 200. The magnet array 212 includes a plurality of permanent magnets 215 arranged in the movement direction D2. The coil array 512 includes a plurality of coils 513. The coils 513 are arranged in the movement direction D2 to form the linear actuator 501 with the permanent magnets 215. The coil array 512 applies a force along the movement direction D2 to the magnet array 212 in response to the supply of electric power. As described above, the linear actuator is an actuator that generates a force along the arrangement direction of the plurality of permanent magnets in the magnet array and the plurality of coils in the coil array in a non-contact manner. The coil array 512 further applies a force along the gravity direction D1 to the magnet array 212 in response to the supply of electric power.

The back yoke 511 is fixed below the upper facing portion 310 and supports the magnet array 212 from above. The back yoke 511 is made of magnetic materials such as electromagnetic steel sheets, and constitutes a magnetic path of magnetic fluxes generated by the magnet array 212.

In the permanent magnets 215, the permanent magnets 215 whose polarities are opposite to each other are alternately arranged. For example, in the permanent magnets 215, the permanent magnet 215 whose N pole is directed to the coil array 512 and the permanent magnet 215 whose S pole is directed to the coil array 512 are alternately arranged.

The number of poles of the magnet array 212 (the number of the permanent magnets 215 included in the magnet array 212) may be greater than the number of poles corresponding to the number of the coils of the coil array 512 (the number of the coils 513 included in the coil array 512). The number of poles corresponding to the number of coils of the coil array 512 is the number of poles to obtain desired thrust characteristics in the movement direction D2. As an example, FIG. 8 illustrates a configuration in which eight poles are corresponding to six coils. While eight poles are corresponding to the six coils, one more pole is added and nine poles are arranged for the six coils.

A side force generator 520 is placed on the lateral facing portion 320 and applies a non-contact force (a first additional non-contact force F11) to the workpiece holder 200 to follow the movement of the moving body 300. The first additional non-contact force may be active (controllable). For example, the side force generator 520 faces the window 142 from the side and faces the side magnet array 223 in the protruding portion 120 across the window 142.

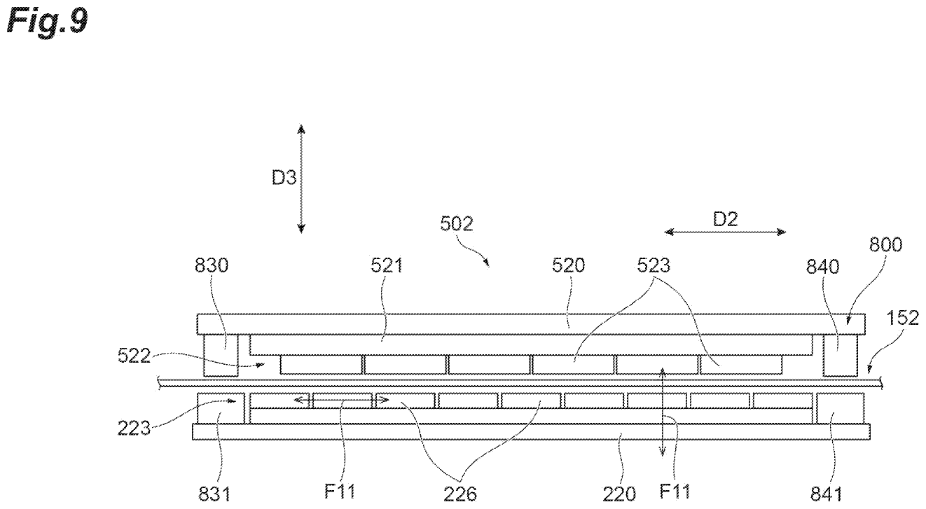

As illustrated in FIG. 9, the side force generator 520 includes a side coil base 521 and a side coil array 522. The side coil array 522 constitutes a linear actuator 502 with the side magnet array 223 placed in the workpiece holder 200. The side magnet array 223 includes a plurality of permanent magnets 226 arranged in the movement direction D2. The side coil array 522 includes a plurality of coils 523. The coils 523 are arranged in the movement direction D2 to form the linear actuator 502 with the permanent magnets 226. The side coil array 522 applies a force along the movement direction D2 to the side magnet array 223 in response to the supply of electric power. The side coil array 522 further applies a force along the width direction D3 to the side magnet array 223 in response to the supply of electric power.

The side coil base 521 is secured to the side of the lateral facing portion 320 and provides lateral support for the side coil array 522. The side coil base 521 is made of a substantially non-magnetic material such as aluminum-based metals.

In the permanent magnets 226, similarly to the permanent magnets 215, the permanent magnets 226 having mutually opposite polarities are alternately arranged. The number of poles of the permanent magnets 226 may be greater than the number of poles corresponding to the number of coils of the side coil array 522.

A side force generator 530 is placed on the lateral facing portion 330 and applies a non-contact force (a second additional non-contact force F21) to the workpiece holder 200 to follow the movement of the moving body 300. The first additional non-contact force may be active (controllable). For example, the side force generator 530 faces the window 152 from the side and faces the side magnet array 233 in the protruding portion 120 across the window 152.

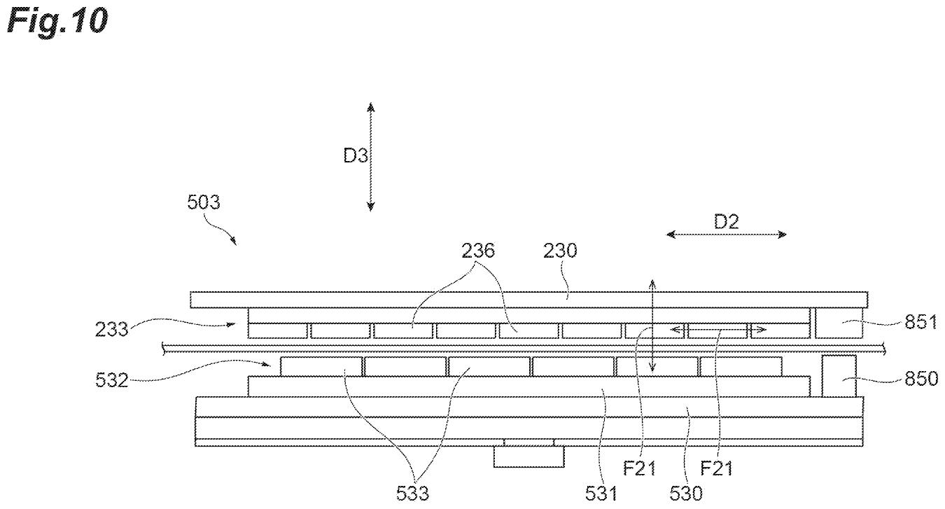

As illustrated in FIG. 10, the side force generator 530 includes a side coil base 531 and a side coil array 532. The side coil array 532 constitutes a linear actuator 503 with the side magnet array 233 placed in the workpiece holder 200. The side magnet array 233 includes a plurality of permanent magnets 236 arranged in the movement direction D2. The side coil array 532 includes a plurality of coils 533. The coils 533 are arranged in the movement direction D2 to form the linear actuator 503 with the permanent magnets 236. The side coil array 532 applies a force along the movement direction D2 to the side magnet array 233 in response to the supply of electric power. The side coil array 532 further applies a force along the width direction D3 to the side magnet array 233 in response to the supply of electric power.

The side coil base 531 is secured to the side of the lateral facing portion 330 and provides lateral support for the side coil array 532. The side coil base 531 is made of a substantially non-magnetic material such as aluminum-based metals.

In the permanent magnets 236, similarly to the permanent magnets 215, the permanent magnets 236 having mutually opposite polarities are alternately arranged. The number of poles of the permanent magnets 236 may be greater than the number of poles corresponding to the number of coils of the side coil array 532.

As illustrated in FIG. 7, the side force generator 520 and the side force generator 530 may be arranged at different positions (heights) in the gravity direction D1 so as to apply force to the workpiece holder 200 at different positions (heights) in the gravity direction D1. With this configuration, the relative position and relative posture of the workpiece holder 200 with respect to the moving body 300 can be adjusted with a lot of degrees of freedom by the linear actuator 501, the linear actuator 502, and the linear actuator 503. Hereinafter, the relative position of the workpiece holder 200 with respect to the moving body 300 is simply referred to as “relative position”, and the relative posture of the workpiece holder 200 with respect to the moving body 300 is simply referred to as “relative posture”.

For example, the relative position in the movement direction D2 can be adjusted by the forces applied by the linear actuator 501, the linear actuator 502, and the linear actuator 503 along the movement direction D2. The relative posture about the axis along the width direction D3 (hereinafter referred to as “relative posture around the width direction D3”) can be adjusted by the relationship between the force applied by the linear actuator 501 along the movement direction D2 and the force applied by at least one of the linear actuator 502 and the linear actuator 503 along the movement direction D2. The relative posture about the axis along the gravity direction D1 (hereinafter referred to as “relative posture around the gravity direction D1”) can be adjusted by the relationship between the force applied by the linear actuator 502 along the movement direction D2 and the force applied by the linear actuator 503 along the movement direction D2. The relative position in the gravity direction D1 can be adjusted by the force applied by the linear actuator 501 along the gravity direction D1. The relative position in the width direction D3 can be adjusted by the force applied by the linear actuator 502 and the linear actuator 503 along the width direction D3.

Since the position where the linear actuator 502 applies force to the workpiece holder 200 and the position where the linear actuator 503 applies force to the workpiece holder 200 are different in the gravity direction D1, the relative posture around the axis along the movement direction D2 (hereinafter referred to as “relative posture around the movement direction D2”) can be adjusted by the relationship between the force applied along the width direction D3 by the linear actuator 502 and the force applied along the width direction D3 by the linear actuator 503. Furthermore, the relative posture around the width direction D3 can be adjusted by the relationship between the force applied by the linear actuator 502 along the movement direction D2 and the force applied by the linear actuator 503 along the movement direction D2 in addition to the relationship between the force applied by the linear actuator 501 along the movement direction D2 and the force applied by the linear actuator 502, 503 along the movement direction D2.

A center of gravity P1 of the workpiece holder 200 may be located in the gravity direction D1 between an action area R1 of the non-contact force applied by the side force generator 520 and an action area R2 of the non-contact force applied by the side force generator 530. The stability of relative posture can be further improved. It should be noted that the workpiece holder 200 may include two or more side magnet arrays 223 spaced apart from each other and correspondingly have two or more side coil arrays 523 where the side force generators 520 are spaced apart from each other. A space between the two or more side coil arrays 523 is included in the action area R1. Similarly, the workpiece holder 200 may have two or more side magnet arrays 233 that are spaced apart from one another and correspondingly have two or more side coil arrays 533 where the side force generators 530 are spaced apart from one another. A space between the two or more side coil arrays 533 is included in the action area R2.

FIG. 7 illustrates a case where the window 142 and the window 152 are arranged at different positions in the gravity direction D1 in accordance with the side magnet array 223 and the side magnet array 233 being arranged at different positions in the gravity direction D1. Even if the side magnet array 223 and the side magnet array 233 are located at different positions in the gravity direction D1, the window 142 and the window 152 may be located at the same position in the gravity direction D1. By matching the heights of the window 142 and the window 152, deformation or the like of the side partition wall 140 and the side partition wall 150 caused by asymmetry of the shape may be reduced.

The arrangement of the actuators capable of adjusting relative position in the gravity direction D1, relative position in the movement direction D2, relative position in the width direction D3, relative posture around the gravity direction D1, relative posture around the movement direction D2, and relative posture around the width direction D3 is not limited to the example described above, and can be modified. In the example described above, the linear actuator 501 applies force from above, and the linear actuator 502 and the linear actuator 503 exert force from each side in the width direction D3. However, the linear actuator 501 may apply force from below. Also, both the linear actuator 502 and the linear actuator 503 may apply force from the same direction in the width direction D3. Further, the linear actuator 501 and the linear actuator 502 may apply force from below, and the linear actuator 503 may apply force from one direction in the width direction D3. In any case, the above-described three types of relative positions and three types of relative postures may be adjusted.

Weight Reducer

As illustrated in FIG. 8, in this the transport system 1, the weight reducer 400 is constituted by a part of the linear actuator 501. For example, the weight reducer 400 comprises the permanent magnets 215 located in the workpiece holder 200 and the back yoke 511 in the force generator 510. The permanent magnets 215 and the back yoke 511 generate an attractive force as the passive non-contact force described above. As described above, with the configuration in which the moving body 300 faces the workpiece holder 200 from above and a non-contact force is generated in the workpiece holder 200 from the force generator 510 disposed in the moving body 300, an element of the linear actuator 501 that generates a passive attractive force can be utilized as the weight reducer 400 to save space.

The center of gravity P1 of the workpiece holder 200 may be located within a generation area R3 of an attractive force or repulsive force generated by the weight reducer 400 in the width direction D3. The stability of the posture of the workpiece holder 200 is improved. For example, the center of gravity P1 of the workpiece holder 200 may be located in the width direction D3 in a range where the widths of the permanent magnet 215 and the widths of the back yoke 511 overlap. The holding unit 240 may further include a balance weight 247 for adjusting the position of the center of gravity P1 in the width direction D3. It should be noted that the workpiece holder 200 may have two or more magnet arrays 212 spaced apart from each other and correspondingly two or more pairs of the coil array 512 and the back yoke 511 with the force generators 510 spaced apart from each other. Two or more pairs of the coil array 512 and the back yoke 511 are included in the generation area R3.

Driver

Returning to FIG. 7, the driver 600 moves the moving body 300 in the movement direction D2. For example, the driver 600 includes a stator 620 extending along the movement direction D2 and a mover 630, and moves the mover 630 with respect to the stator 620 by a magnetic pole such as a permanent magnet and a moving magnetic field generated by the coil. The driver 600 may be a moving magnet type in which a permanent magnet is provided in the mover 630, or a moving coil type in which a coil is provided in the mover 630. The mover 630 is secured to the driven arm 350 of the moving body 300 described above.

The driver 600 may transmit a driving force to the moving body 300 at the center of gravity of the combined body of the workpiece holder 200 and the moving body 300 in the gravity direction D1. The stability of the posture of the workpiece holder 200 can be further improved. As described above, since the mover 630 is fixed to the driven arm 350 of the moving body 300, the position where the driving force acts on the moving body 300 is the position where the driving force acts on the mover 630. The center of gravity of the combined body is located in an area R4 where the driving force acts on the mover 630 in the gravity direction D1. The driver 600 may be configured to apply a driving force to the mover 630 at two or more places having different heights. A space between the two or more places is included in the area R4.

Sensor

The sensor 700 detects the position of the moving body 300 in the movement direction D2. The “position of the moving body 300” is a position with respect to the transport housing 10. In the transport housing since all devices operate with respect to the transport housing 10, the position with respect to the transport housing 10 is hereinafter referred to as an “absolute position” for convenience.

The sensor 700 includes a linear scale 710 and the reader 720. The linear scale 710 is fixed on the base plate 110, extends along the movement direction D2, and includes magnetic or optical scale information. The reader 720 is fixed to the sensor holder 360 of the above-described the moving body 300 so as to face the linear scale 710, reads the scale information of the linear scale 710 while moving together with the moving body 300, and detects the absolute position of the moving body 300.

The relative sensor 800 detects at least one of relative position and relative posture of the workpiece holder 200 with respect to the moving body 300. As an example, the relative sensor 800 is configured to detect all of the above-described three types of relative positions and three types of relative postures from the outside of the transport chamber 11 in a non-contact manner. As illustrated in FIG. 8, the relative sensor 800 includes a displacement sensor 860 and gap sensors 810, 820. The displacement sensor 860 is secured to the upper facing portion 310 of the moving body 300 and detects displacements in the movement direction D2 of a target 861 secured to the upper unit 210 in the workpiece holder 200. By way of example, the displacement sensor 860 is a magnetostrictive sensor and includes magnetostrictive lines along the movement direction D2. The displacement sensor 860 detects displacements of the target 861 based on torsional strains generated in the magnetostrictive lines by magnets of the target 861. The relative position in the movement direction D2 may be detected by the displacement sensor 860.

The gap sensors 810, 820 are fixed to the upper facing portion 310 at different positions in the movement direction D2, and detect distances to targets 811, 821 fixed to the upper unit 210 in the workpiece holder 200. With the gap sensors 810, 820, the relative position in the gravity direction D1 and the relative posture around the width direction D3 are detected.

As illustrated in FIG. 9, the relative sensor 800 further includes gap sensors 830, 840. The gap sensors 830, 840 are fixed to the lateral facing portion 320 at different positions in the movement direction D2, and distances to targets 831, 841 fixed to the side unit 220 in the workpiece holder 200 are detected. As illustrated in FIG. 10, the relative sensor 800 further include a gap sensor 850. The gap sensor 850 is fixed to the lateral facing portion 330 and detects distances to a target 851 fixed to the side unit 230 of the workpiece holder 200. The gap sensors 830, 840 and the gap sensor 850 are provided at different positions (heights) in the gravity direction D1. A relative position in the width direction D3 may be detected by the gap sensors 830, 840, 850. A relative posture around the gravity direction D1 may be detected based on a relationship between a detection result by the gap sensor 830 and a detection result by the gap sensor 840. A relative posture around the movement direction D2 may be detected based on a relationship between a detection result by the gap sensors 830, 840 and a detection result by the gap sensor 850.

For example, gap sensors 810, 820, 830, 840, 850 are eddy-current sensors. The eddy-current sensor includes a coil that generates a magnetic flux at a frequency, and detects a distance to a positioning target based on an impedance change of the coil corresponding to an eddy current generated in a conductive member of the positioning target.

The configuration of the relative sensor 800 described above is an example, and variously modied. The relative sensor 800 described above is configured to detect the workpiece holder 200 displacements along six positioning lines that are independent of one another. That three or more positioning lines are independent of each other means that in the three or more positioning lines, vectors along each positioning line cannot be synthesized by vectors along the remaining two or more positioning lines. Note that the vector along the positioning line means a vector along the positioning line and located on the positioning line.

As an example of the case where three or more positioning lines are not independent of each other, there is a case where three positioning lines are parallel to each other in the same plane. By adjusting the magnitudes of the vectors along two of the three positioning lines, the vector along the remaining one positioning line may be synthesized.

In the above-described the relative sensor 800, a vector along a positioning line by the displacement sensor 860 cannot be synthesized by vectors along positioning lines by the gap sensors 810, 820, 830, 840, 850. The same applies to a vector along the positioning line of the gap sensor 810, a vector along the positioning line of the gap sensor 820, a vector along the positioning line of the gap sensor 830, a vector along the positioning line of the gap sensor 840, and a vector along the positioning line of the gap sensor 850.

As described above, any configuration can detect three types of relative positions and three types of relative postures as long as it is configured to detect displacements of the workpiece holder 200 along six positioning lines independent from each other. For example, the displacement sensor 860 may be constituted by a gap sensor similar to the gap sensor 810 or the like. The gap sensors of the transport system 1 may be placed in the lateral facing portion 320, and the gap sensors of the processing unit 2 may be placed in the lateral facing portion 330.

Control Unit

Returning to FIG. 5, the control unit 900 controls the non-contact force of the force generator 510 to control at least one of the relative position and relative posture of the workpiece holder 200. For example, the control unit 900 controls the non-contact force of the force generator 510 and the non-contact force of the side force generators 520, 530 so as to control the above-described three types of relative positions and three types of relative postures. For example, the control unit 900 controls electric power supplied to the coil array 512 of the force generator 510, electric power supplied to the side coil array 522 of the side force generator 520, and electric power supplied to the side coil array 532 of the side force generator 530 so as to maintain each of the three types of relative positions and the three types of relative postures within a predetermined target range.

The predetermined target range is defined so that, at least, the above-described rollers 213, 214 do not contact the lateral inner surfaces 135, 136, the rollers 224, 225 do not contact the lower inner surface 145 and the upper inner surface 146, and the rollers 234, 235 do not contact the lower inner surface 155 and the upper inner surface 156 that.

The control unit 900 may control the force generator 510 and the side force generators 520, 530 based on the relative position and relative posture detected by the relative sensor 800. For example, the control unit 900 controls the force generator 510 and the side force generators 520, 530 so as to maintain the relative position in the movement direction D2 detected by the relative sensor 800, the relative position in the gravity direction D1, and the relative posture around the width direction D3 within target ranges. The control unit 900 controls the side force generator 520 and the side force generator 530 so as to maintain the relative position in the width direction D3 detected by the relative sensor 800, the relative posture around the gravity direction D1, and the relative posture around the movement direction D2 within a target range.

The control unit 900 may control the non-contact force in the force generator 510 to control the absolute position of the workpiece holder 200 based on the relative position and relative posture detected by the relative sensor 800. For example, the control unit 900 calculates the target values of relative position and relative posture based on the absolute position of the moving body 300 detected by the sensor 700 and the target values of absolute position and absolute posture of the workpiece holder 200, and controls the force generator 510 and the side force generators 520, 530 so that the relative position and the relative posture approach the target values.

By utilizing the control of the relative position based on the detection result by the relative sensor 800 for the control of the absolute position of the workpiece holder, the absolute position of the workpiece holder may readily be adjusted with accuracy by combining rough positioning by the moving body and precise positioning by the force generator.

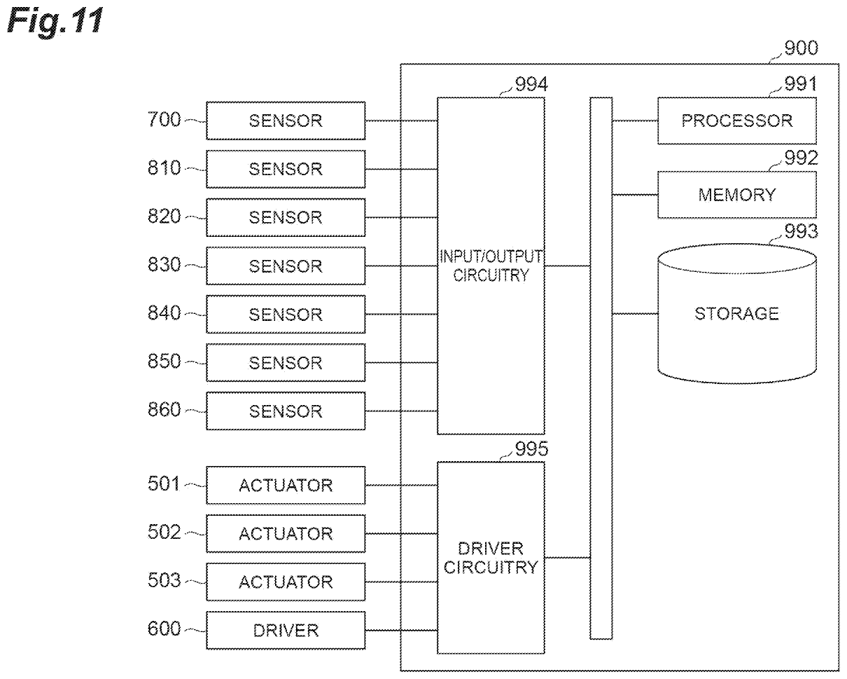

FIG. 11 is a diagram illustrating a hardware configuration of the control unit 900. As illustrated in FIG. 11, the control unit 900 includes circuitry 990. The circuitry 990 includes at least one processor 991, a memory 992, storage 993, input/output circuitry 994, and driver circuitry 995. The storage 993 includes a computer-readable storage medium, such as a nonvolatile semiconductor memory. The storage 993 stores a control program for the transport device 30. The control program includes a program that causes the control unit 900 to control the force generator 510 and the side force generators 520, 530 based on the detection result by the sensor 700 and the detection result by the relative sensor 800.

The memory 992 temporarily stores the program loaded from the storage medium of the storage 993 and the calculation result by the processor 991. The processor 991 executes the program in cooperation with the memory 992. The input/output circuitry 994 inputs and outputs electrical signals to and from the relative sensor 800 in accordance with commands from the processor 991. The driver circuitry 995 outputs driving electric power to the linear actuator 501, 502, 503 and the driver 600 in accordance with commands from the processor 991.

Cooling Structure

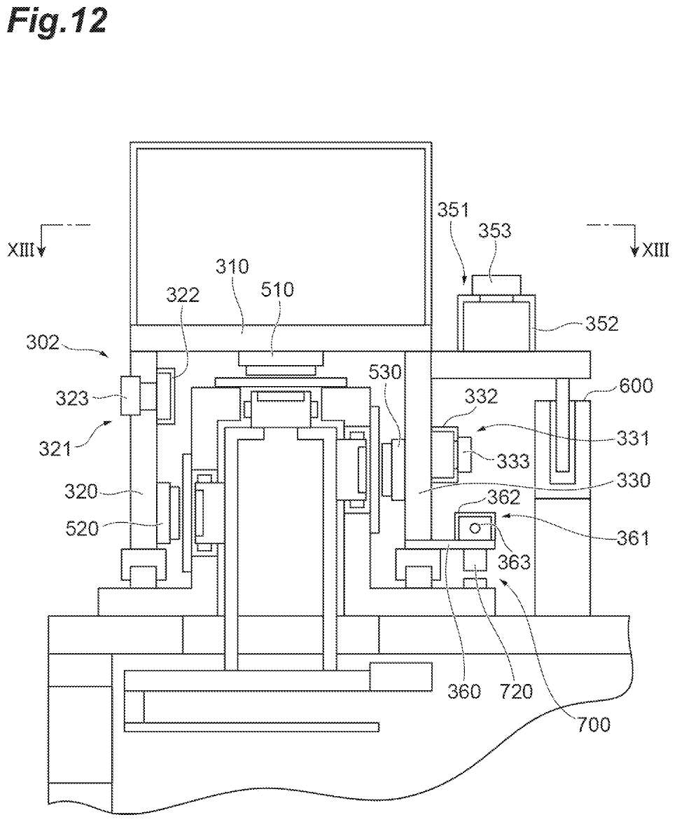

The transport system 1 may further include a cooling system 302, as illustrated in FIG. 12. For example, the cooling system 302 includes a cooler 321 and a cooler 331 cooling the lateral facing portion 320 and the lateral facing portion 330, respectively. The cooler 321 cools the side force generator 520 located on the lateral facing portion 320 by cooling the lateral facing portion 320. The cooler 331 cools the side force generator 530 located on the lateral facing portion 330 by cooling the lateral facing portion 330. By utilizing the lateral facing portion 320 and the lateral facing portion 330 as heat radiation media, the side force generator 520 and the side force generator 530 can be efficiently cooled.

For example, the cooler 321 cools the lateral facing portion 320 by generating an air flow that flows along the lateral facing portion 320. The cooler 321 includes a cooling duct 322 and a fan 323. The cooling duct 322, together with the lateral facing portion 320, define an air flow path along the movement direction D2. The fan 323 forcibly generates an airflow in the cooling duct 322 by blowing air into the cooling duct 322 or sucking air from the cooling duct 322.

The cooler 331 likewise cools the lateral facing portion 330 by generating an air flow that flows along the lateral facing portion 330. The cooler 331 includes a cooling duct 332 and a fan 333. The cooling duct 332, together with the lateral facing portion 330, define an air flow path along the movement direction D2. The fan 333 forcibly generates an airflow in the cooling duct 332 by blowing air into the cooling duct 332 or sucking air from the cooling duct 332.

The cooling system 302 may further include a cooler 351 for cooling the driven arm 350. The cooler 351 prevents heat transfer from the driver 600 to the moving body 300 and heat transfer from the moving body 300 to the driver 600, respectively, by cooling the driven arm 350. For example, the cooler 351 cools the driven arm 350 by generating an air flow that flows along the driven arm 350. The cooler 351 includes a cooling duct 352 and a fan 353. The cooling duct 352, together with the driven arm 350, define an air flow path along the movement direction D2. The fan 353 forcibly generates an airflow in the cooling duct 352 by blowing air into the cooling duct 352 or sucking air from the cooling duct 352.

The cooling system 302 may further include a cooler 361 for cooling the sensor holder 360. The cooler 361 prevents heat transfer from the moving body 300 to the reader 720 of the sensor 700 by cooling the sensor holder 360. By preventing heat transfer to the reader 720, the detection accuracy of the position of the moving body 300 can be improved. For example, the cooler 361 cools the sensor holder 360 by generating an air flow that flows along the sensor holder 360. The cooler 361 includes a cooling duct 362 and a blower connector 363. The cooling duct 362, together with the sensor holder 360, define an air flow path along the movement direction D2. The blower connector 363 introduces air from a pressurized source such as an air compressor into the cooling duct 362 to forcibly generate an air flow in the cooling duct 362.

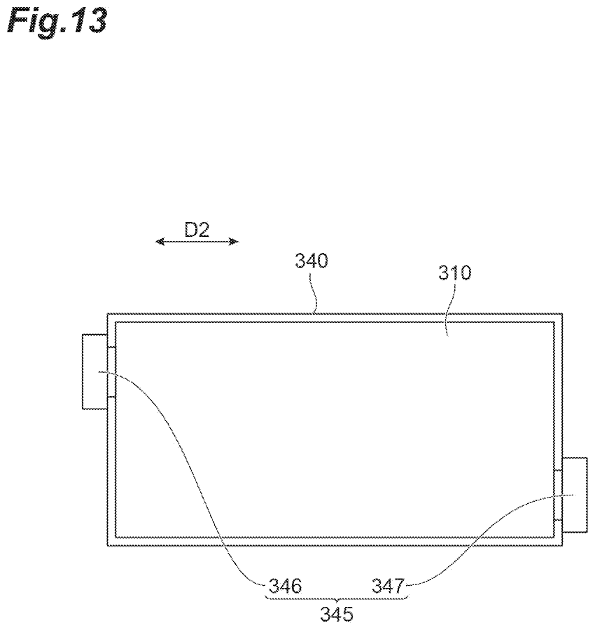

The cooling system 302 may further include a cooler 345 for cooling the upper facing portion 310. The cooler 345 cools the force generator 510 located in the upper facing portion 310 by cooling the upper facing portion 310. For example, the cooler 345 cools the upper facing portion 310 by generating an air flow that flows along the upper facing portion 310. As illustrated in FIG. 13, the cooler 345 includes a fan 346 and a fan 347. The fan 346 and the fan 347 generate airflow in the case 340 along the movement direction D2. With this configuration, the case 340 can be utilized for cooling the upper facing portion 310. Although all of the cooler 321, the cooler 331, the cooler 345, the cooler 351, and the cooler 361 described above are air-cooling type, the cooling method is not limited to the air-cooling method, and may be a water-cooling method. In addition, a Peltier element, a heat pipe, or the like may be used to cool each part.

### SUMMARY

The above disclosure includes the following configurations.

(1) A transport system 1 including: a workpiece holder 200 capable of holding a workpiece; a moving body 300 facing the workpiece holder 200 at least in a gravity direction D1 and movable in a movement direction D2 intersecting the gravity direction D1; a weight reducer 400 generating an attractive force or a repulsive force with the workpiece holder 200 so as to reduce the weight of the workpiece holder 200; a force generator 510 disposed on the moving body 300 to face the workpiece holder 200 in the gravity direction D1 and applying a non-contact force to the workpiece holder 200 to follow the movement of the moving body 300 while levitating the workpiece holder 200 having the weight that is reduced; and a control unit 900 configured to control the non-contact force of the force generator 510 to control at least one of a position and a posture of the workpiece holder 200 with respect to the moving body 300. Since this the transport system 1 includes the weight reducer 400, a non-contact force generated for levitating the workpiece holder 200 can be reduced. Accordingly, the energy consumption for generating the non-contact force can be reduced. Therefore, power consumption may be suppressed.

(2) The system 1 according to (1), further including a magnet array 212 disposed in the workpiece holder 200 and including a plurality of permanent magnets arranged in the movement direction D2, wherein the force generator 510 includes a coil array 512 including a plurality of coils 513 arranged in the movement direction D2 to form a linear actuator with the magnet array 212, and wherein the control unit 900 is configured to control an electric power supplied to the coil array 512 to control the non-contact force.

The non-contact force can readily be controlled in accordance with the electric power. The relative position in the movement direction D2 may finely be adjusted by using a linear actuator capable of displacing the workpiece holder 200 in the movement direction D2 for adjustment of the positional relationship between the workpiece holder 200 and the moving body 300 despite the relative displacement is a minute level.

(3) The transport system 1 according to (2), wherein the number of permanent magnets included in the magnet array 212 is greater than the number of coils 513 included in the coil array 512.

Stability of the posture of the workpiece holder 200 can be further improved.

(4) The transport system 1 according to any one of (1) to (3), wherein the moving body 300 is disposed above the workpiece holder 200 in the gravity direction D1, and the weight reducer 400 is disposed in the moving body 300 and generates an attractive force with respect to the workpiece holder 200.

The object to which the magnetic force acts can be constituted of a soft magnetic material, and the use of the magnet can be reduced. By providing the weight reducer 400 in the moving body 300 which is less displaced relative to the workpiece holder 200, the weight reducer 400 can be made compact.

(5) The transport system 1 according to (4), wherein the weight reducer 400 has at least one of: a permanent magnet or a soft magnetic member that generates an attractive force between itself and a permanent magnet disposed in the workpiece holder 200; and a permanent magnet that generates an attractive force between itself and a soft magnetic member disposed in the workpiece holder 200.

Gravity can be reduced without consuming electric power. In addition, even in maintenance work performed without supplying electric power, the position of the workpiece holder 200 may be kept near the moving body 300 by making the workpiece holder 200 follow the movement of the moving body 300. Thus, recovery work after maintenance is facilitated.

(6) The transport system 1 according to (5), wherein the force generator 510 includes at least one coil 513 that applies the non-contact force to the permanent magnet disposed in the workpiece holder 200, and wherein the weight reducer 400 is a soft magnetic member and is a back yoke of the at least one coil 513.

By using the soft magnetic member also as a yoke of the force generator 510, space saving can be achieved.

(7) The transport system 1 according to any one of (1) to (6), further including a sensor 800 configured to detect a relative position of the workpiece holder 200 with respect to the moving body 300, wherein the control unit 900 is configured to control the non-contact force of the force generator 510 so as to control an absolute position of the workpiece based at least on the relative position.

By utilizing the control of the relative position based on the detection result by the sensor 800 to control the absolute values of the workpiece, the absolute values of the workpiece can readily be adjusted with accuracy by combining rough positioning by the moving body 300 and precise positioning by the force generator 510.

(8) The transport system 1 according to any one of (1) to (7), wherein the moving body 300 includes a first lateral facing portion 320 and a second the lateral facing portion 330 each facing the workpiece holder 200 on each side of the width direction D3 intersecting the movement direction D2 and the gravity direction D1, wherein the transport system 1 further comprises: a first side force generator 520 disposed in the first lateral facing portion 320 and configured to apply a non-contact force to the workpiece holder 200 to follow movement of the moving body 300; and a second side force generator 530 disposed in the second the lateral facing portion 330 to apply a non-contact force to the workpiece holder 200 to follow movement of the moving body 300, and wherein the control unit 900 is configured to control the non-contact forces of a first side force generator 520 and the second side force generator 530 so as to control at least one of the position and posture of the workpiece holder 200 with respect to the moving body 300.

(9) The transport system 1 according to (8), wherein the first side force generator 520 and the second side force generator 530 are disposed at different positions in the gravity direction D1.

With the first side force generator 520 and the second side force generator 530, the posture of the workpiece holder 200 around an axis along the movement direction D2 can readily be adjusted. Thus, the posture of the workpiece holder 200 can readily be adjusted.

(10) The transport system 1 according to (9), wherein the center of gravity of the workpiece holder 200 is located in the gravity direction D1 between an action area of the non-contact force applied by the first side force generator 520 and an action area of the non-contact force applied by the second side force generator 530.

The stability of the posture of the workpiece holder 200 can be further improved.

(11) The transport system 1 according to any one of (8) to (10), further including, in the workpiece holder 200, a first side magnet array 223 and a second side magnet array 233 disposed on each side of the width direction D3, the first side magnet array 223 and the second side magnet array 233 each including a plurality of permanent magnets arranged in the movement direction D2, wherein the first side force generator 520 includes a first side coil array 522 including a plurality of coils 513 arranged in the movement direction D2 to form a linear actuator with the first side magnet array 223, wherein the second side force generator 530 includes a second side coil array 532 including a plurality of coils 513 arranged in the movement direction D2 to form a linear actuator with the second side magnet array 233, and wherein the control unit 900 is configured to control electric power supplied to the first side coil array 522 and the second side coil array 532 so as to control the non-contact force.

The non-contact force can readily be controlled in accordance with the electric power. The relative position in the movement direction D2 may finely adjusted by using a plurality of linear actuators capable of displacing the workpiece holder 200 in the movement direction D2 for adjustment of the positional relationship between the workpiece holder 200 and the moving body 300 despite the relative displacement is a minute level.

(12) The transport system 1 according to (11), wherein the moving body 300 is disposed above the workpiece holder 200, wherein the weight reducer 400 is disposed in the moving body 300 to generate an attractive force between the weight reducer 400 the workpiece holder 200, wherein the transport system 1 includes a first partition wall 140 between the first lateral facing portion 320 and the workpiece holder 200, and wherein the first partition wall 140 includes: a first window 142 facing the first side magnet array 223; and a first support wall 147 supporting the first window 142 and located below the first side magnet array 223.

Both the strength of the first partition wall 140 and the ease of transmission of the non-contact force can be achieved. In addition, falling of the workpiece holder 200 can be prevented by the first support wall 147.

(13) The transport system 1 according to (12), wherein the transport system 1 includes a second partition wall 150 between the second the lateral facing portion 330 and the workpiece holder 200, wherein the second partition wall 150 includes: a second window 152 facing the second side magnet array 233; and a second support wall 157 supporting the second window 152 and located below the second side magnet array 233, wherein the first side magnet array 223 and the second side magnet array 233 are located at different positions in the gravity direction D1, and wherein the first window 142 and the second window 152 are located at the same position in the gravity direction D1. By matching the heights of the first window 142 and the second window 152, deformation or the like of the first partition wall 140 and the second partition wall 150 caused by asymmetry of the shape may be prevented.

(14) The transport system 1 according to (12) or (13), wherein the workpiece holder 200 includes: an upper portion 211 facing the moving body 300 in the gravity direction D1; a first side 221 extending downward from the upper portion 211 to support the first side magnet array 223; and a second side 231 extending downward from the upper portion 211 to support the second side magnet array 233, and wherein the upper portion 211, the first side 221, and the second side 231 are separable from one another.

The maintainability can be improved.

(15) The transport system 1 according to any one of (12) to (14), wherein the workpiece holder 200 includes a first roller 224 provided under the first side magnet array 223, and wherein, when the workpiece holder 200 is supported by the first support wall 147, the first roller 224 contacts the first support wall 147 and rolls in response to movement of the workpiece holder 200.

The workpiece holder 200 can more smoothly follow the moving body 300 during maintenance.

(16) The transport system 1 according to any one of (1) to (15), further including a driver 600 that transmits a driving force to the moving body 300 at a center of gravity in the gravity direction D1 of a combination of the workpiece holder 200 and the moving body 300 to move the moving body 300.

The stability of the posture of the workpiece holder 200 can be further improved.

(17) The transport system 1 according to any one of (1) to (16), further including a first robot 40A and a second robot 40B disposed at different positions in the movement direction D2, wherein the moving body 300 is configured to move between a first position allowing delivery of the workpiece between the first robot 40A and the workpiece holder 200 and a second position allowing delivery of the workpiece between the second robot 40B and the workpiece holder 200.

(18) The transport system 1 according to any one of (1) to (17), wherein the center of gravity of the workpiece holder 200 is located within a generation area of an attractive force or a repulsive force generated by the weight reducer 400 in a width direction D3 intersecting the gravity direction D1 and the movement direction D2.

The stability of the posture of the workpiece holder 200 is improved.

(19) A transport system 1 including: a workpiece holder 200 capable of holding a workpiece; a moving body 300 disposed above the workpiece holder 200 and movable in a movement direction D2 intersecting a gravity direction D1; and a force generator 510 disposed on the moving body 300 so as to face the workpiece holder 200 in the gravity direction D1 and configured to apply a non-contact force to the workpiece holder 200 so as to follow a movement of the moving body 300 while levitating the workpiece holder 200.

With the configuration in which the movement of the workpiece holder 200 is made to follow the movement of the moving body 300 disposed above the workpiece holder 200 by the non-contact force, the passive attractive force included in the non-contact force for the levitation of the workpiece holder 200 may be utilized and energy consumption for generating the non-contact force may be reduced. Therefore, both suppression of power consumption and space saving may be achieved.

(20) A transport system 1 including: a workpiece holder 200 capable of holding a workpiece; a moving body 300 facing the workpiece holder 200 at least in the gravity direction D1 and movable in the movement direction D2 intersecting the gravity direction D1; a force generator 510 disposed on the moving body 300 to face the workpiece holder 200 in the gravity direction D1, and configured to apply a non-contact force to the workpiece holder 200 so as to follow movement of the moving body 300 while levitating the workpiece holder 200; a sensor 800 configured to detect a relative position of the workpiece holder 200 with respect to the moving body 300; and a control unit 900 configured to control the non-contact force of the force generator 510 so as to control an absolute position of the workpiece holder 200 based on at least relative position.

By utilizing the control system for maintaining the relative position of the workpiece holder 200 with respect to the moving body 300 also for controlling the absolute position of the workpiece holder 200, the absolute position of the workpiece holder 200 can readily be adjusted with accuracy by combining rough positioning by the moving body 300 and precise positioning by the force generator 510.

(21) A transport system 1 including: a workpiece holder 200 capable of holding a workpiece; a moving body 300 facing the workpiece holder 200 at least in a gravity direction D1 and movable in a movement direction D2 intersecting the gravity direction D1; a magnet array 212 disposed on the workpiece holder 200 and including a plurality of permanent magnets arranged in the movement direction D2; a coil array 512 disposed on the moving body 300 to face the workpiece holder 200 in the gravity direction D1, and including a plurality of coils 513 arranged in the movement direction D2 so as to constitute a linear actuator together with the magnet array 212; and a control unit 900 configured to control electric power supplied to the coil array 512 so that the workpiece holder 200 levitates and follows the movement of the moving body 300. The non-contact force can readily be controlled according to the electric power. The relative position in the movement direction D2 may finely be adjusted by using a linear actuator capable of displacing the workpiece holder 200 in the movement direction D2 for adjustment of the positional relationship between the workpiece holder 200 and the moving body 300 despite the relative displacement is a minute level.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A transport system comprising:
a workpiece holder configured to hold a workpiece;
a moving body facing the workpiece holder at least in a gravity direction and movable in a movement direction intersecting the gravity direction;
a weight reducer configured to apply a static non-contact force to the workpiece holder to reduce a weight of the workpiece holder;
a force generator disposed on the moving body to face the workpiece holder in the gravity direction, the force generator configured to apply a controllable non-contact force to the workpiece holder so as to follow a movement of the moving body while levitating the workpiece holder having the reduced weight; and
circuitry configured to control the controllable non-contact force generated by the force generator to control a relative position of the workpiece holder with respect to the moving body.

2. The transport system according to claim 1, further comprising a magnet array disposed in the workpiece holder and including a plurality of permanent magnets arranged in the movement direction,
wherein the force generator comprises a coil array including a plurality of coils arranged in the movement direction to form a linear actuator together with the magnet array, and
wherein the circuitry is configured to control an electric power supplied to the coil array so as to control the controllable non-contact force.

3. The transport system according to claim 2, wherein a number of permanent magnets included in the magnet array is greater than a number of coils included in the coil array.

4. The transport system according to claim 1, wherein the moving body is disposed above the workpiece holder in the gravity direction, and
wherein the weight reducer is disposed in the moving body and applies an attractive force to the workpiece holder as the static non-contact force.

5. The transport system according to claim 4, wherein the weight reducer applies the attractive force to the workpiece holder by a static magnetic field.

6. The transport system according to claim 5, wherein the force generator includes at least one coil for generating the controllable non-contact force to at least one permanent magnet disposed in the workpiece holder, and
wherein the weight reducer is a back yoke of the at least one coil, the back yoke including a soft magnetic member that applies the attractive force to the workpiece holder by the static magnetic field generated by the at least one permanent magnet.

7. The transport system according to claim 1, further comprising:
a first sensor configured to detect a relative position of the workpiece holder with respect to the moving body; and
a second sensor configured to detect an absolute position of the workpiece holder with respect to a fixed original position,
wherein the circuitry is configured to control the controllable non-contact force to cause the absolute position to follow a target position with respect to the fixed original position by controlling the relative position based on the detected relative position and the detected absolute position.

8. The transport system according to claim 1 wherein the moving body includes a first lateral facing portion and a second lateral facing portion facing with each other along a width direction intersecting the movement direction and the gravity direction, wherein the workpiece holder is located between the first lateral facing portion and the second lateral facing portion,
wherein the transport system further comprises:
a first side force generator disposed in the first lateral facing portion and configured to apply a first additional non-contact force to the workpiece holder to follow the movement of the moving body; and
a second side force generator disposed in the second lateral facing portion and configured to apply a second additional non-contact force to the workpiece holder to follow the movement of the moving body, and
wherein the circuitry is further configured to control the first additional non-contact force and the second additional non-contact force to control the relative position.

9. The transport system according to claim 8, wherein the first side force generator and the second side force generator are disposed at different positions in the gravity direction.

10. The transport system according to claim 9, wherein a center of gravity of the workpiece holder is located in the gravity direction between an application area of the first additional non-contact force and an application area of the second additional non-contact force.

11. The transport system according to claim 8, further comprising:
a first side magnet array disposed on the workpiece holder to face the first side force generator, the first side magnet array including a plurality of first permanent magnets arranged in the movement direction; and
a second side magnet array disposed on the workpiece holder to face the second side force generator, the second side magnet array including a plurality of second permanent magnets arranged in the movement direction,
wherein the first side force generator includes a first side coil array including a plurality of first coils arranged in the movement direction to form a first linear actuator together with the first side magnet array,
wherein the second side force generator includes a second side coil array including a plurality of second coils arranged in the movement direction to form a second linear actuator together with the second side magnet array, and
wherein the circuitry is configured to control electric power supplied to the first side coil array and the second side coil array to control the first additional non-contact force and the second additional non-contact force.

12. The transport system according to claim 11, wherein the moving body is disposed above the workpiece holder,
wherein the weight reducer is disposed in the moving body and applies an attractive force to the workpiece holder as the static non-contact force,
wherein the transport system includes a first partition wall between the first lateral facing portion and the workpiece holder, and
wherein the first partition wall includes:
a first window facing the first side magnet array; and
a first support wall supporting the first window and located below the first side magnet array.

13. The transport system according to claim 12, wherein the transport system includes a second partition wall between the second lateral facing portion and the workpiece holder,
wherein the second partition wall includes:
a second window facing the second side magnet array; and
a second support wall supporting the second window and located below the second side magnet array,
wherein the first side magnet array and the second side magnet array are disposed at different heights in the gravity direction, and
wherein the first window and the second window are disposed at same heights in the gravity direction.

14. The transport system according to claim 12, wherein the workpiece holder comprises:
an upper portion facing the moving body in the gravity direction;
a first side portion extending downward from the upper portion to support the first side magnet array; and
a second side portion extending downward from the upper portion to support the second side magnet array, and
wherein the upper portion, the first side portion, and the second side portion are detachable from one another.

15. The transport system according to claim 12, wherein the workpiece holder includes a first roller provided under the first side magnet array,
wherein the first roller is supported by the first support wall during a period in which the controllable non-contact force is not applied to the workpiece holder, and
wherein the first roller supported by the first support wall rolls in response to movement of the workpiece holder along the movement direction.

16. The transport system according to claim 1, further comprising a base actuator configured to apply a driving force to the moving body at a center of gravity in the gravity direction of a combination of the workpiece holder and the moving body to move the moving body along the movement direction.

17. The transport system according to claim 1, further comprising a first robot and a second robot disposed at different positions in the movement direction,
wherein the moving body is configured to move between a first position for transferring the workpiece to and from the first robot and a second position for transferring the workpiece between to and from the second robot.

18. The transport system according to claim 1, wherein a center of gravity of the workpiece holder is located within an application area of the static non-contact force in a width direction intersecting the gravity direction and the movement direction.

19. A transport system comprising:
a workpiece holder configured to hold a workpiece;
a moving body disposed above the workpiece holder in a gravity direction and movable in a movement direction intersecting the gravity direction; and
a force generator disposed on the moving body to face the workpiece holder in the gravity direction, the force generator configured to apply a controllable non-contact force to the workpiece holder to follow a movement of the moving body while levitating the workpiece holder.

20. A transport system comprising:
a workpiece holder configured to hold a workpiece;
a moving body facing the workpiece holder at least in a gravity direction and movable in a movement direction intersecting the gravity direction;
a force generator disposed on the moving body to face the workpiece holder in the gravity direction, the force generator configured to apply a controllable non-contact force to the workpiece holder to follow a movement of the moving body while levitating the workpiece holder;
a first sensor configured to detect a relative position of the workpiece holder with respect to the moving body;
a second sensor configured to detect an absolute position of the workpiece holder with respect to a fixed original position; and
a circuitry configured to control the controllable non-contact force generated by the force generator to cause the absolute position to follow a target position with respect to the fixed original position by controlling a relative position of the workpiece holder with respect to the moving body based at least in part on the detected relative position and the detected absolute position.
